(19) United States
(12) Patent Application Publication
(10) Pub. No.: US 2026/0123256 A1
(43) Pub. Date: Apr. 30, 2026

(54) DISPLAY DEVICE

(71) Applicant: LG Display Co., Ltd., Seoul (KR)

(72) Inventors: Jihyeop KIM, Paju-si (KR); Jinsuk LEE, Paju-si (KR); Kyunghee KIM, Paju-si (KR); HyunSik KIM, Paju-si (KR); Junggi KIM, Paju-si (KR); SeongYong UHM, Paju-si (KR); Dohyung KIM, Paju-si (KR)

(73) Assignee: LG Display Co., Ltd., Seoul (KR)

(21) Appl. No.: 19/307,463

(22) Filed: Aug. 22, 2025

(30) Foreign Application Priority Data
Oct. 31, 2024 (KR) 10-2024-0152287

(51) Int. Cl. H10K 59/80; H10K 59/122; H10K 59/50

(52) U.S. Cl. CPC H10K 59/8792; H10K 59/122; H10K 59/50; H10K 59/873

(57) ABSTRACT

A display device includes a substrate, a bank, a first light emitting layer disposed on a first pixel electrode, a second light emitting layer disposed on a second pixel electrode, a common electrode disposed on the first light emitting layer and the second light emitting layer, an inorganic encapsulation layer disposed on the common electrode, a first photochromic layer disposed on the inorganic encapsulation layer and overlapping the bank, an organic encapsulation layer disposed on the first photochromic layer, and a second photochromic layer disposed on the organic encapsulation layer and overlapping the first photochromic layer to reduce reflectance and increase viewing angle.

### CROSS-REFERENCE TO RELATED APPLICATION

This application claims priority from Korean Patent Application No. 10-2024-0152287, filed on Oct. 31, 2024, which is hereby incorporated by reference for all purposes as if fully set forth herein.

### BACKGROUND

### Technical Field

Embodiments of the disclosure relate to a display device.

### Description of the Related Art

As the information society develops, demand for display devices for displaying images is increasing in various forms. Various display devices, such as liquid crystal display devices and organic light emitting display devices, are being utilized in recent years.

When the display panel is used outdoors, external light may be perceived by the user, reducing the visibility of the display panel.

If the viewing angle of the display panel is narrow, the image may not be visible to users on the side of the display panel.

Accordingly, it would be advantageous have a display device that overcomes these and other deficiencies and disadvantages of current solutions.

### BRIEF SUMMARY

Embodiments of the disclosure provide a display device capable of reducing reflectance through a second photochromic layer.

Embodiments of the disclosure provide a display device capable of increasing the viewing angle through a second photochromic layer.

Embodiments of the disclosure provide a display device capable of increasing luminance through a second photochromic layer.

Embodiments of the disclosure provide a display device capable of lower power consumption by reducing reflectance and increasing viewing angle.

In one or more embodiments, a display device includes a substrate, a first pixel electrode disposed on the substrate, a second pixel electrode disposed on the substrate and spaced apart from the first pixel electrode, a bank disposed on the first pixel electrode and the second pixel electrode, overlapping each of a portion of the first pixel electrode and a portion of the second pixel electrode, and having an opening, a first light emitting layer disposed on the first pixel electrode, a second light emitting layer disposed on the second pixel electrode, a common electrode disposed on the first light emitting layer and the second light emitting layer, an inorganic encapsulation layer disposed on the common electrode, a first photochromic layer disposed on the inorganic encapsulation layer and overlapping the bank, an organic encapsulation layer disposed on the first photochromic layer, and a second photochromic layer disposed on the organic encapsulation layer and overlapping the first photochromic layer.

The display device further comprises a first color filter disposed on the organic encapsulation layer and overlapping the first light emitting layer, and a second color filter disposed on the organic encapsulation layer and overlapping the second light emitting layer. A portion of the first color filter is positioned on a portion of the second photochromic layer, and a portion of the second color filter is positioned on a portion of the second photochromic layer.

The display device further comprises a touch electrode disposed on the organic encapsulation layer. The touch electrode has an opening overlapping each of the first light emitting layer and the second light emitting layer. A portion except for the opening in the touch electrode overlap the first photochromic layer and the second photochromic layer. The display device further comprise an insulation layer on the touch electrode. The second photochromic layer be disposed on the insulation layer.

The organic encapsulation layer includes an organic material having a single refractive index.

The organic encapsulation layer includes a plurality of organic layers having different refractive indices. The plurality of organic layers includes a first organic layer having a first refractive index, and a second organic layer disposed on the first organic layer and having a second refractive index larger than the first refractive index.

The first photochromic layer and the second photochromic layer are capable of turning transparent or black. The first photochromic layer and the second photochromic layer turn black when exposed to ultraviolet (UV) light. The first photochromic layer and the second photochromic layer turn transparent in a low-illuminance environment.

Embodiments of the disclosure provide a display device comprising a substrate, a bank disposed on the substrate and having an opening, a light emitting layer disposed in the opening, an inorganic encapsulation layer disposed on the light emitting layer and the bank, a first photochromic layer disposed on the inorganic encapsulation layer and overlapping the bank, and an organic encapsulation layer disposed on the first photochromic layer and including a plurality of organic layers having different refractive indices.

The above summary is not limiting to the disclosure or claims and additional features, benefits, and advantages of the concepts of the disclosure are explained below with reference to the accompanying drawings.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a schematic view of a display device according to embodiments of the present disclosure;

FIG. 2 is a schematic view of a display panel of the display device of FIG. 1;

FIG. 3 is a cross-sectional view of the display panel of FIG. 1 along line A-A in FIG. 1;

FIGS. 4 and 5 are schematic cross-sectional views of a display panel according to embodiments of the present disclosure;

FIG. 6 is a detail view of a photochromic bank, a photochromic pixel defining layer or first photochromic layer, and a second photochromic layer of the display panel of FIGS. 4 and 5;

FIGS. 7 and 8 are schematic cross-sectional views of a display panel according to embodiments of the present disclosure; and

FIGS. 9 and 10 are schematic cross-sectional views of an encapsulation layer of the display panel of FIGS. 7 and 8.

### DETAILED DESCRIPTION

In the following description of examples or embodiments of the disclosure, reference will be made to the accompanying drawings in which specific examples or embodiments of various implementations of the concepts of the disclosure are shown by way of illustration. In the drawings, the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description makes the subject matter in some embodiments of the disclosure unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements. Thus, a first element may be a second element and vice versa.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms are used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “” fully encompasses all the meanings of the term “can.” Unless otherwise specified in the following description, relative terms are interpreted to include an error range of plus or minus 5% of the stated value, dimension, size, etc.

Hereinafter, various embodiments of the disclosure are described in detail with reference to the accompanying drawings.

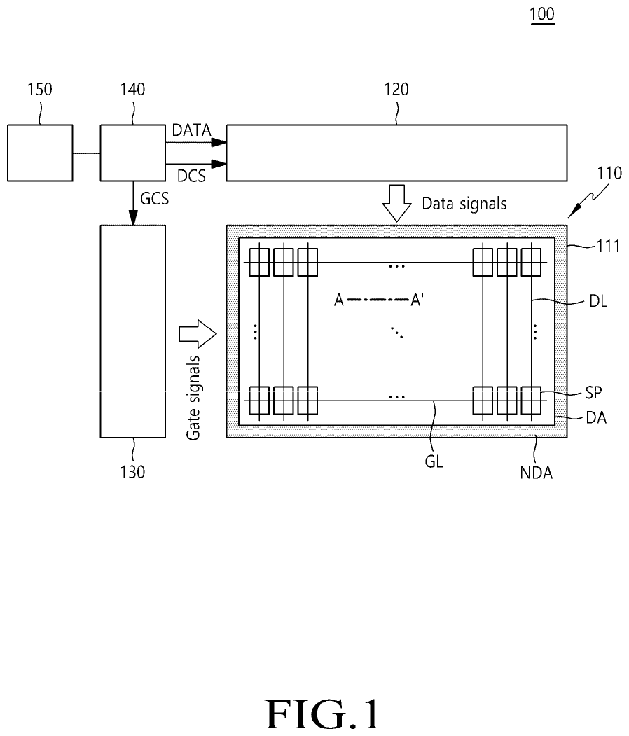

FIG. 1 is a schematic view of a display device 100 according to embodiments of the disclosure.

Referring to FIG. 1, the display device 100 includes a display panel 110 and display driving circuits, as components for displaying images. The display driving circuit is a circuit for driving the display panel 110. The display driving circuits include a data driving circuit 120, a gate driving circuit 130, and a controller 140, but embodiments of the disclosure are not limited thereto.

The display panel 110 includes a substrate 111 and a plurality of subpixels SP disposed on the substrate 111.

The substrate 111 includes a display area DA capable of image display and a non-display area NDA positioned outside the display area DA. A plurality of subpixels SP for image display are disposed in the display area DA. The non-display area NDA includes a pad area PA positioned in a column direction from the display area DA.

Various types of signal lines for driving a plurality of subpixels SP are disposed on the substrate 111 of the display panel 110.

The structure of each of the plurality of subpixels SP vary according to the type of the display device 100. For example, when the display device 100 is a self-emission display device in which the subpixels SP emit light by themselves, each subpixel SP includes a light emitting element that emits light by itself, one or more transistors, and one or more capacitors, but embodiments of the disclosure are not limited thereto.

The data driving circuit 120 is a circuit for driving a plurality of data lines DL. The data driving circuit 120 outputs data signals to the plurality of data lines DL.

The data driving circuit 120 receives digital image data DATA from the controller 140 and converts the received image data DATA into analog data signals and output them to the plurality of data lines DL. The data driving circuit 120 is connected outside the display area DA of the display panel 110, but as another example, the data driving circuit 120 may be disposed in the display area DA of the display panel 110.

The gate driving circuit 130 is a circuit for driving the plurality of gate lines GL, and outputs gate signals to the plurality of gate lines GL.

The gate driving circuit 130 receives a first gate voltage corresponding to a turn-on level voltage and a second gate voltage corresponding to a turn-off level voltage, along with various gate driving control signals GCS, generates gate signals, and supplies the generated gate signals to the plurality of gate lines GL.

In the display device 100 according to embodiments of the disclosure, the gate driving circuit 130 is embedded in a gate in panel (GIP) type in the display panel 110, but embodiments of the disclosure are not limited thereto. When the gate driving circuit 130 is of the gate in panel type, the gate driving circuit 130 is formed on the substrate 111 of the display panel 110 during the manufacturing process of the display panel 110.

For example, the gate driving circuit 130 is disposed in the non-active area NDA of the display panel 110. As another example, the gate driving circuit 130 may be disposed in the display area DA of the display panel 110.

The controller 140 is a device for controlling the data driving circuit 120 and the gate driving circuit 130 and controls driving timings or the timing of driving for the plurality of data lines DL and driving timings or the timing of driving for the plurality of gate lines GL.

The controller 140 supplies a data driving control signal DCS to the data driving circuit 120 to control the data driving circuit 120 and supplies a gate driving control signal GCS to the gate driving circuit 130 to control the gate driving circuit 130.

The controller 140 receives input image data from the host system 150 and supplies image data DATA to the data driving circuit 120 based on the input image data.

The controller 140 is mounted on a printed circuit board or a flexible printed circuit and is electrically connected with the data driving circuit 120 and the gate driving circuit 130 through the printed circuit board or the flexible printed circuit.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, and/or the position of the touch.

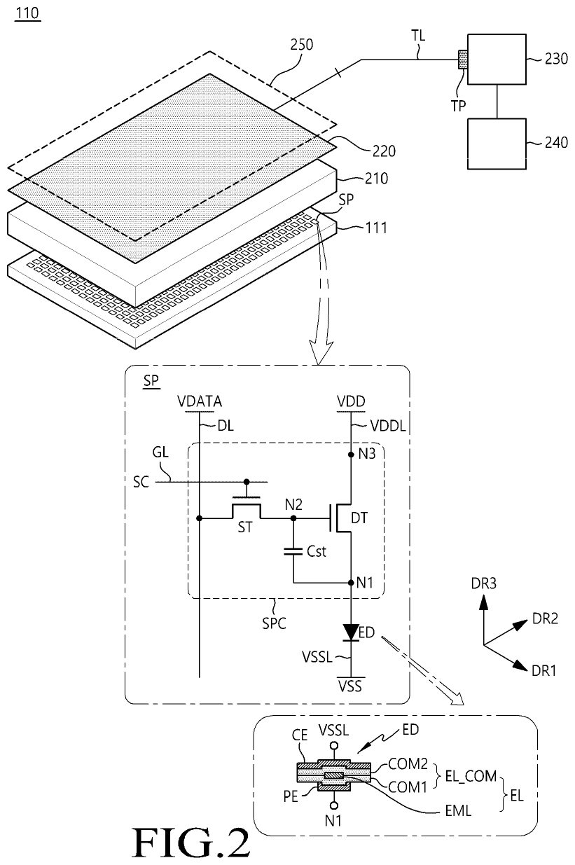

FIG. 2 is a schematic view illustrating of the display panel 110.

Referring to FIG. 2, the display panel 110 includes a substrate 111, a plurality of subpixels SP disposed on or in the substrate 111, and an encapsulation layer 210 on the substrate 111. The encapsulation layer 210 may also be referred to as an encapsulation substrate or an encapsulation unit.

Referring to FIG. 2, when the display device 100 according to embodiments of the disclosure is a self-luminous display device, each of the plurality of subpixels SP disposed on the substrate 111 includes a light emitting element ED and a subpixel circuit SPC for driving the light emitting element ED.

Referring to FIG. 2, the subpixel circuit SPC includes a plurality of transistors and at least one capacitor for driving the light emitting element ED, but embodiments of the disclosure are not limited thereto. In the disclosure, the subpixel circuit SPC drives the light emitting element ED by supplying a driving current to the light emitting element ED at a predetermined timing. The light emitting element ED is driven by a driving current to emit light.

The plurality of transistors include a driving transistor DT for driving the light emitting element ED and a scan transistor ST that is turned on or off according to the scan signal SC.

The driving transistor DT supplies a driving current to the light emitting element ED.

The scan transistor ST is configured to control the electrical state of a corresponding node in the subpixel circuit SPC or to control the state or operation of the driving transistor DT. The gate node of the scan transistor ST is electrically connected to the gate line GL.

The at least one capacitor includes a storage capacitor Cst for maintaining a constant voltage during a frame.

To drive the subpixel SP, a data signal VDATA as an image signal and a scan signal SC as a gate signal are applied to the subpixel SP. Further, for driving the subpixel SP, a common pixel driving voltage including the driving voltage VDD and the base voltage VSS are applied to the subpixel SP.

The light emitting element ED includes a pixel electrode PE, an intermediate layer EL, and a common electrode CE. The intermediate layer EL is disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode.

When the light emitting element ED is an organic light emitting element, the intermediate layer EL includes a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML is disposed for each subpixel SP. The common intermediate layer EL_COM is commonly disposed across the plurality of subpixels SP, but embodiments of the disclosure are not limited thereto.

The light emitting layer EML is disposed for each emission area. The common intermediate layer EL_COM is commonly disposed across a plurality of emission areas and non-emission areas, but embodiments of the disclosure are not limited thereto.

For example, the first common intermediate layer COM1 includes a hole injection layer HIL, an electron blocking layer EBL, and a hole transport layer HTL, but embodiments of the disclosure are not limited thereto. The second common intermediate layer COM2 includes an electron transport layer ETL, a hole blocking layer HBL, and an electron injection layer EIL, but embodiments of the disclosure are not limited thereto.

The hole injection layer injects holes from the pixel electrode PE to the hole transport layer, the hole transport layer transports the holes to the light emitting layer EML, the electron injection layer injects electrons from the common electrode CE to the electron transport layer, and the electron transport layer transports electrons to the light emitting layer EML.

The common electrode CE is electrically connected to the base voltage line VSSL. The base voltage VSS, which is one type of the common pixel driving voltage, is applied to the common electrode CE through the base voltage line VSSL. The pixel electrode PE is electrically connected directly or indirectly (through another transistor) to the first node N1 of the driving transistor DT of each subpixel SP. In the disclosure, “base voltage VSS” may also be referred to as a “low-potential power voltage” or a “low-potential voltage,” and “base voltage line VSSL” may also be referred to as a “low-potential power voltage line” or a “low-potential voltage line.”

Each light emitting element ED includes portions where the pixel electrode PE, the light emitting layer in the intermediate layer LE, and the common electrode CE overlap. A predetermined light emitting area is formed by each light emitting element ED. For example, the light emitting area of each light emitting element ED includes an overlapping area of the pixel electrode PE, the intermediate layer EL, and the common electrode CE.

The driving transistor DT is a driving transistor for supplying a driving current to the light emitting element ED. The driving transistor DT is connected between a driving voltage line VDDL and the light emitting element ED.

The driving transistor DT includes a first node N1, a second node N2, and a third node N3. The first node N1 is electrically connected to the light emitting element ED, the second node N2 receives a data signal VDATA, and the third node N3 receives a driving voltage VDD from the driving voltage line VDDL. The driving transistor DT is connected to the first node N1 and the third node N3.

In the driving transistor DT, the second node N2 is a gate node, the first node N1 may be a source node or a drain node, and the third node N3 may be a drain node or a source node. Hereinafter, for convenience of description, an example is described in which in the driving transistor DT, the second node N2 is a gate node, the first node N1 is a source node, and the third node N3 is a drain node, but embodiments of the disclosure are not limited thereto.

The scan transistor ST included in the subpixel circuit SPC illustrated in FIG. 2 is a switching transistor for transferring the data signal VDATA, which is an image signal, to the second node N2, which is the gate node of the driving transistor DT.

The scan transistor ST is controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST is electrically connected to the scan line SCL.

The storage capacitor Cst is electrically connected between the first node N1 and the first node N2 of the driving transistor DT. The storage capacitor Cst includes a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure.

When the display panel 110 has a top emission structure, at least a portion of the subpixel circuit SPC overlaps at least a portion of the light emitting element ED in a vertical direction. Accordingly, the area of the emission area increases and the aperture ratio increases.

When the display panel 110 has a bottom emission structure, the subpixel circuit SPC not overlap the light emitting element ED in the vertical direction.

As illustrated in FIG. 2, the subpixel circuit SPC has a 2T (Transistor)1C (Capacitor) structure including two transistors DT and ST and one capacitor Cst. In some cases, the subpixel circuit SPC further includes one or more transistors or further includes one or more capacitors.

For example, the subpixel circuit SPC has an 8T1C structure including 8 transistors and 1 capacitor. As another example, the subpixel circuit SPC has a 6T2C structure including 6 transistors and 2 capacitors. As another example, the subpixel circuit SPC has a 7T1C structure including 7 transistors and 1 capacitor. Embodiments of the disclosure are not limited thereto.

Since the circuit elements (e.g., the light emitting element ED implemented as an organic light emitting diode (OLED) including an organic material) in each subpixel SP are vulnerable to external moisture or oxygen, the encapsulation layer 210 is disposed on the display panel 110. The encapsulation layer 210 prevents external moisture or oxygen from penetrating into circuit elements (e.g., the light emitting element ED). The encapsulation layer 210 may be configured in various forms so that the light emitting elements ED do not contact moisture or oxygen. For example, the encapsulation layer 210 is constituted of two or more layers in which organic films and inorganic films are alternately stacked, but embodiments of the disclosure are not limited thereto.

Referring to FIG. 2, the display device 100 according to embodiments of the disclosure includes a touch sensor layer 220 including a plurality of sensor electrodes to sense the user's touch, a touch driving circuit 220 configured to drive the plurality of sensor electrodes, and a touch controller 230 configured to determine the presence or absence of a touch or touch coordinates using the sensing result (touch sensing data) of the touch driving circuit 220.

The touch sensor layer 220 is embedded in the display panel 110. For example, the touch sensor layer 210 is disposed on the encapsulation layer 210 in the display panel 110. The touch sensor layer 220 may also be referred to as a touch unit.

The display panel 110 further includes a plurality of touch pads TP electrically connected to the touch driving circuit 220 and a plurality of touch routing lines for electrically connecting the plurality of sensor electrodes included in the touch sensor layer 220 to the plurality of touch pads TP connected to the touch driving circuit 220.

The color filter layer 250 is disposed on the touch sensor layer 220. The color filter layer 250 converts a color of light passing through the color filter layer 250.

The color filter layer 250 further includes an insulation layer disposed under the black matrix. The insulation layer may be a color filter buffer layer. The insulation layer includes an inorganic material.

The color filter layer 250 further includes an insulation layer disposed on the color filter. The insulation layer is an overcoat layer. The insulation layer include an organic material.

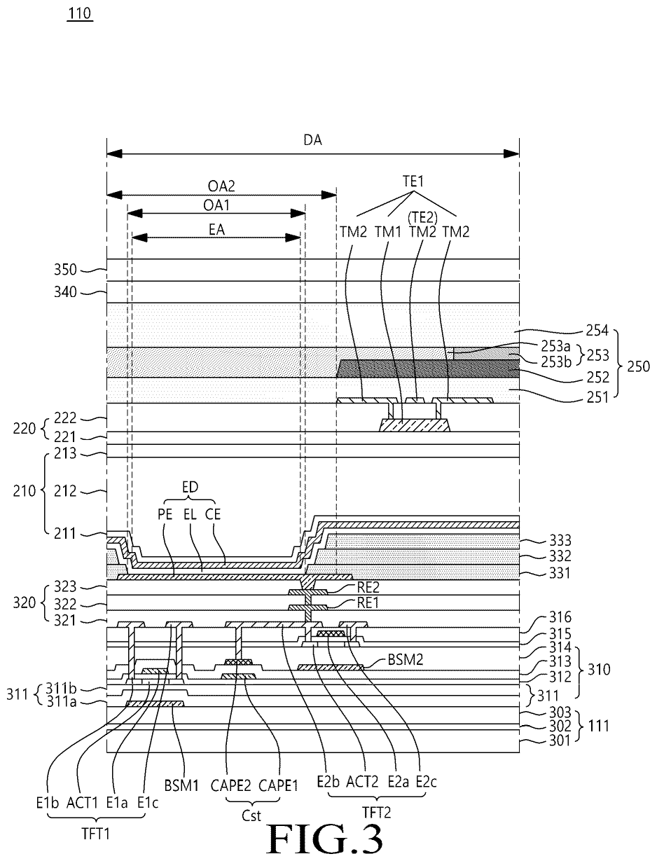

FIG. 3 is a cross-sectional view of the display panel 110.

Referring to FIG. 3, the display panel 110 according to embodiments of the disclosure includes a transistor unit (or transistor array), a light emitting element unit (light emitting element or light emitting assembly), and an encapsulation unit (encapsulation assembly or encapsulation layer stack), but embodiments of the disclosure are not limited thereto.

The substrate 111 may be a single layer or multiple layers. When the substrate 111 includes multiple layers, the substrate 111 includes a first substrate 301, an intermediate layer 302, and a second substrate 303. The intermediate layer 302 is positioned between the first substrate 301 and the second substrate 303. For example, each of the first substrate 301 and the second substrate 303 may be a polyimide (PI) layer, but embodiments of the disclosure are not limited thereto. The intermediate layer 302 may be an inorganic insulation layer, but embodiments of the disclosure are not limited thereto. When an electric charge is charged to the first substrate PI1 which is a polyimide layer, the intermediate layer 302 prevents the electric charge from affecting transistors disposed on the second substrate 303 through the second substrate 303 which is a polyimide layer.

The transistor unit includes a substrate 111, insulation layers 310, 311, 312, 313, 314, 315, and 316 on the substrate 111, thin film transistors TFT1 and TFT2, a storage capacitor Cst, and various electrodes or signal lines.

The thin film transistors TFT1 and TFT2 included in the transistor unit include a first thin film transistor TFT1 and a second thin film transistor TFT2.

The first thin film transistor TFT1 includes a first active layer ACT1, a first electrode E1a, a second electrode E1b, and a third electrode E1c. The first active layer ACT1 is a first semiconductor layer, but embodiments of the disclosure are not limited thereto. For example, the first active layer ACT1 is formed of an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The first electrode E1a is a gate electrode, the second electrode E1b is a source electrode or a drain electrode, and the third electrode E1c is a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto.

The second thin film transistor TFT2 includes a second active layer ACT2, a fourth electrode E2a, a fifth electrode E2b, and a sixth electrode E2c. The second active layer ACT2 is a second semiconductor layer, but embodiments of the disclosure are not limited thereto. For example, the second active layer ACT2 may be formed of an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

The fourth electrode E2a is a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 of the second thin film transistor TFT2 is positioned higher from the substrate 111 than the first active layer ACT1 of the first thin film transistor TFT1.

The first buffer layer 311 is disposed under the first active layer ACT1 of the first thin film transistor TFT1, and a second buffer layer 314 is disposed under the second active layer ACT2 of the second thin film transistor TFT2. For example, the first active layer ACT1 of the first thin film transistor TFT1 is positioned on the first buffer layer 311, and the second active layer ACT2 of the second thin film transistor TFT2 is positioned on the second buffer layer 314. The second buffer layer 314 is positioned higher than the first buffer layer 311.

The storage capacitor Cst is disposed in various metal layers in the display panel 110. For example, the storage capacitor Cst includes a first capacitor electrode CAPE1 and a second capacitor CAPE2.

The light emitting element unit includes a plurality of light emitting elements ED disposed on at least one planarization layer 321, 322, and 323. Each of the plurality of light emitting elements ED includes a pixel electrode PE, an intermediate layer EL, and a common electrode CE.

The encapsulation unit includes an encapsulation layer 210 on the plurality of light emitting elements ED. The encapsulation layer 210 may be a single layer or multiple layers, but embodiments of the disclosure are not limited thereto.

Hereinafter, a structure or a vertical structure of the display panel 110 according to embodiments of the disclosure is described in more detail with reference to FIG. 3.

Referring to FIG. 3, the first buffer layer 311 is disposed on the substrate 111. The first buffer layer 311 may be a single layer or multiple layers, but embodiments of the disclosure are not limited thereto. When the first buffer layer 311 includes multiple layers, the first buffer layer 311 includes an upper buffer layer 311a and a lower buffer layer 311b.

The first active layer ACT1 of the first thin film transistor TFT1 is disposed on the first buffer layer 311. The first active layer ACT1 includes a channel area in which a channel is formed, a source connection area on one side of the channel area, and a drain connection area on the other side of the channel area.

The first insulation layer 312 is disposed on the first active layer ACT1 of the first thin film transistor TFT1. The first gate electrode E1a of the first thin film transistor TFT1 is disposed on the first insulation layer 312. The second insulation layer 313 is disposed on the first gate electrode E1a of the first thin film transistor TFT1. The first insulation layer 312 may be a gate insulation layer, but embodiments of the disclosure are not limited thereto. The second insulation layer 313 may be an interlayer insulation layer, but embodiments of the disclosure are not limited thereto.

The second buffer layer 314 is disposed on the second insulation layer 313.

The second active layer ACT2 of the second thin film transistor TFT2 is disposed on the second buffer layer 314. The second active layer ACT2 includes a channel area in which a channel is formed, a source connection area on one side of the channel area, and a drain connection area on the other side of the channel area.

The third insulation layer 315 is disposed on the second active layer ACT2 of the second thin film transistor TFT2. The second gate electrode E2a of the second thin film transistor TFT2 is disposed on the third insulation layer 315. The fourth insulation layer 316 is disposed on the second gate electrode E2a of the second thin film transistor TFT2. The third insulation layer 315 is a gate insulation layer, but embodiments of the disclosure are not limited thereto. The fourth insulation layer 316 is an inter-layer insulation layer, but embodiments of the disclosure are not limited thereto.

The first source electrode E1b and the first drain electrode E1c of the first thin film transistor TFT1, and the second source electrode E2b and the second drain electrode E2c of the second thin film transistor TFT2 are disposed on the fourth insulation layer 316.

The first source electrode E1b and the first drain electrode E1c of the first thin film transistor TFT1 are connected to the source connection area and the drain connection area, respectively, of the first active layer ACT1 through holes of the fourth insulation layer 316, the third insulation layer 315, the second buffer layer 314, the second insulation layer 313, and the first insulation layer 312.

The second source electrode E2b and the second drain electrode E2c of the second thin film transistor TFT2 are connected to the source connection area and the drain connection area, respectively, of the second active layer ACT2 through the holes of the fourth insulation layer 316 and the third insulation layer 315.

The first source electrode E1b and the first drain electrode E1c of the first thin film transistor TFT1, and the second source electrode E2b and the second drain electrode E2c of the second thin film transistor TFT2 include a first metal and are disposed in the first metal layer. Here, the first metal and the first metal layer may be referred to as a first source-drain metal and a first source-drain metal layer, respectively.

The second source electrode E2b of the second thin film transistor TFT2 is electrically connected to the second capacitor electrode CAPE2 through holes of the fourth insulation layer 316, the third insulation layer 315, and the second buffer layer 314.

For example, the first thin film transistor TFT1 is the scan transistor ST of FIG. 2, and the second thin film transistor TFT2 is the driving transistor DT of FIG. 2.

Referring to FIG. 3, the transistor unit further includes a first shield metal BSM1 disposed on the substrate 111. The first shield metal BSM1 overlaps the first active layer ACT1 of the first thin film transistor TFT1. The first shield metal BSM1 is disposed under the first active layer ACT1 of the first thin film transistor TFT1. For example, the first shield metal BSM1 may be disposed between the substrate 111 and the first buffer layer 311, or may be disposed between the upper buffer layer 311a and the lower buffer layer 311a.

The transistor unit further includes a second shield metal BSM2 disposed on the substrate 111. The second shield metal BSM2 overlaps the second active layer ACT2 of the second thin film transistor TFT2. The second shield metal BSM2 is disposed under the second active layer ACT2 of the second thin film transistor TFT2.

For example, the second shield metal BSM2 is disposed in a metal layer between the second insulation layer 313 and the second buffer layer 314. The second shield metal BSM2 is disposed in the same metal layer as the second capacitor CAPE2, but embodiments of the disclosure are not limited thereto.

As another example, the second shield metal BSM2 is disposed in the same first gate metal layer as the first gate electrode E1a of the first thin film transistor TFT1.

At least one planarization layer is disposed on the first thin film transistor TFT1 and the second thin film transistor TFT2. In the example of FIG. 3, three planarization layers 321, 322, and 323 are disposed on the first thin film transistor TFT1 and the second thin film transistor TFT2. In some cases, two planarization layers are disposed on the first thin film transistor TFT1 and the second thin film transistor TFT2, but embodiments of the disclosure are not limited thereto.

Referring to FIG. 3, the first planarization layer 321 is disposed on the first source electrode E1b and the first drain electrode E1c of the first thin film transistor TFT1, and the second source electrode E2b and the second drain electrode E2c of the second thin film transistor TFT2. For example, the first planarization layer 321 is disposed on the first thin film transistor TFT1 and the second thin film transistor TFT2. For example, the first planarization layer 321 covers both the first thin film transistor TFT1 and the second thin film transistor TFT2.

Referring to FIG. 3, a first relay electrode RE1 is disposed on the first planarization layer 321. The first relay electrode RE1 electrically connects the second source electrode E2b of the second thin film transistor TFT2 and the pixel electrode PE.

The first relay electrode RE1 is electrically connected to the second source electrode E2b of the second thin film transistor TFT2 through the hole of the first planarization layer 321. The second source electrode E2b of the second thin film transistor TFT2 is electrically connected to the second capacitor electrode CAPE2 of the storage capacitor Cst.

The first relay electrode RE1 is disposed in the second metal layer on the first planarization layer 321 and includes a second metal. The second metal and the second metal layer may be referred to as a second source-drain metal and a second source-drain metal layer, respectively.

The second planarization layer 323 is disposed on the first relay electrode RE1. A second relay electrode RE2 is disposed on the second planarization layer 323. The second relay electrode RE2 allows for the lines included in the display panel 110 to be designed more efficiently. The third planarization layer 323 is disposed on the second relay electrode RE2.

Referring to FIG. 3, the light emitting element unit is disposed on or formed on the third planarization layer 323. The light emitting element ED includes a pixel electrode PE, an intermediate layer EL, and a common electrode CE. The emission area of the light emitting element ED is formed in an area in which the pixel electrode PE, the intermediate layer EL, and the common electrode CE overlap and contact each other.

The pixel electrode PE is disposed on the third planarization layer 323. The pixel electrode PE is electrically connected to the first relay electrode RE1 through the hole of the third planarization layer 323.

The black bank 331 is disposed on the third planarization layer 323. A portion of the black bank 331 may optionally be disposed on the pixel electrode PE. The black bank 331 minimizes reflection of external light.

The bank 332 is disposed on the black bank 331. The opening of the bank 332 exposes a portion of the pixel electrode PE to form the emission area.

The spacer 333 is disposed on the bank 332. The spacer 333 prevents damage due to contact of the fine metal mask used in the manufacturing process.

The intermediate layer EL of the light emitting element ED is disposed on a portion of the pixel electrode PE and the spacer 333. The common electrode CE is disposed on the intermediate layer EL.

Referring to FIG. 3, the encapsulation unit is disposed on the light emitting element unit and is positioned on the common electrode CE. The encapsulation unit includes the encapsulation layer 210 formed on the common electrode CE.

The encapsulation layer 210 prevents moisture or oxygen from penetrating into the light emitting element ED.

Referring to FIG. 3, the encapsulation layer 210 includes a first inorganic encapsulation layer 211, an organic encapsulation layer 212, and a second inorganic encapsulation layer 213, but embodiments of the disclosure are not limited thereto.

The display panel 110 according to embodiments of the disclosure includes a touch sensor. In this case, the display panel 110 according to embodiments of the disclosure includes a touch sensor layer 220 formed on the encapsulation layer 210.

Referring to FIG. 3, the touch sensor layer 220 includes a plurality of touch electrodes TE, and includes a first touch metal TM1 and a second touch metal TM2 to form the plurality of touch electrodes TE. In embodiments of the disclosure, the layer on which the second touch metal TM2 is disposed may be referred to as a sensor metal layer, and the layer on which the first touch metal TM1 is disposed may be referred to as a bridge metal layer.

The touch sensor layer 220 further includes insulation layers, such as a touch buffer layer 221 on the encapsulation layer 210, a touch insulation layer 222 on the touch buffer layer 221, etc. The touch buffer layer 221 may be omitted.

The first touch metal TM1 is disposed between the touch buffer layer 221 and the touch insulation layer 222. The second touch metal TM2 is disposed between the touch insulation layer 222 and the color filter buffer layer251.

Each of the plurality of touch electrodes TE is formed of the second touch metal TM2. Each of the plurality of touch electrodes TE is a mesh type electrode having a plurality of openings, but embodiments of the disclosure are not limited thereto.

The plurality of touch electrodes TE include a first touch electrode TE1 and a second touch electrode TE2. The second touch metal TM2 included in the first touch electrode TE1 is electrically connected through the first touch metal TM1. For example, the second touch metals TM2 that are spaced apart from each other are electrically connected by the first touch metal TM1 to constitute one first touch electrode TE1.

The first touch metal TM1 is disposed on the buffer layer 221. The touch insulation layer 222 is disposed on the first touch metal TM1. The second touch metal TM2 is disposed on the touch insulation layer 222. Some of the second touch metals TM2 are connected to the corresponding first touch metal TM1 through a hole in the touch insulation layer 222.

Referring to FIG. 3, the first touch metals TM1 and the second touch metals TM2 are disposed not to overlap the light emitting element ED. The first touch metals TM1 and the second touch metals TM2 overlap the bank 332.

The plurality of second touch metals TM2 constitute one touch electrode TE. The plurality of second touch metals TM2 are disposed in a mesh form and electrically connected to each other. A portion of the second touch metal TM2 and another portion of the second touch metal TM2 may be electrically connected through the first touch metal TM1 to constitute one touch electrode TE.

The color filter layer 250 is disposed on the touch sensor layer 220.

The color filter layer 250 includes a color filter buffer layer 251, a black matrix 252, a plurality of color filters 253, and an overcoat layer 254.

The color filter buffer layer 251 is disposed on the second touch metal TM2.

The color filter buffer layer 251 may be an inorganic insulation layer. However, the color filter buffer layer 251 may also be an organic insulation layer.

The black matrix 252 is disposed on the color filter buffer layer 251.

The black matrix 252 is disposed to overlap the bank 332. Further, the black matrix 252 is disposed to overlap the black bank 331.

Referring to FIG. 3, the emission area EA is an area in which the pixel electrode PE, the intermediate layer EL, and the common electrode CE overlap. Further, the emission area EA is an area in which the light emitting element ED is disposed. The emission area EA is an area in which the emission layer EML included in the intermediate layer EL is disposed.

The black bank 331 includes a plurality of first opening areas OA1, and the plurality of first opening areas OA1 of the black bank 331 overlap the emission area EA. The first opening area OA1 of the black bank 331 is wider than the emission area EA. Further, while the first opening area OA1 of the black bank 331 is wider than the emission area EA, the emission area EA is positioned to be included in the first opening area OA1 of the black bank 331. Assuming that the emission area EA and the first opening area OA1 of the black bank 331 have a circular shape, the emission area EA is positioned inside or within the first opening area OA1 of the black bank 331.

The black matrix 252 includes a plurality of second opening areas OA2. The plurality of second opening areas OA2 of the black matrix 252 overlap the plurality of first opening areas OA1 of the black bank 331. The area of the second opening area OA2 is larger than the area of the first opening area OA1. When it is assumed that the second opening area OA2 and the first opening area OA1 have circular shapes, the first opening area OA1 is positioned inside or within the second opening area OA2.

The plurality of second opening areas OA2 of the black matrix 252 overlap the emission area EA. The area of the second opening area OA2 is larger than the area of the emission area EA. Assuming that the second opening area OA2 and the emission area EA have circular shapes, the emission area EA is positioned inside or within the second opening area OA2.

Assuming that the emission area EA, the first opening area OA1, and the second opening area OA2 have a circular shape, the emission area EA is positioned inside the first opening area OA1 and the second opening area OA2, and the first opening area OA1 is positioned inside the second opening area OA2.

Since the second opening area OA2 is wider than the emission area EA, light emitted from the emission area EA is emitted not only from the front surface but also from the side surface. Since light is emitted not only from the front surface but also from the side surface, light emitted from the emission area EA is emitted with a predetermined viewing angle.

A plurality of color filters 253 are disposed on the color filter buffer layer 251. Some of the plurality of color filters 253 may be disposed to overlap the black matrix 252.

The plurality of color filters 253 change the color of light passing through the plurality of color filters 253.

The plurality of color filters 253 include a red color filter, a green color filter, and a blue color filter. However, the disclosure is not limited thereto, and the plurality of color filters 253 may include color filters of different colors.

Referring to FIG. 3, the plurality of color filters 253 include a first color filter 253a and a second color filter 253b.

The first color filter 253a is disposed to overlap the light emitting element ED.

The overcoat layer 254 is disposed on the plurality of color filters 253. The overcoat layer 254 includes an organic insulating material. As the color filter layer 250 includes the overcoat layer 254, the upper surface of the color filter layer 250 is planarized.

The adhesive layer 340 is disposed on the overcoat layer 254. The adhesive layer 340 reduces reflectance of external light. The adhesive layer 340 decreases transmittance of external light in a specific wavelength band.

A cover window 350 is disposed on the adhesive layer 340. The cover window 350 is disposed on an uppermost portion of the display panel 110, and the cover window 350 protects the display panel 110 from an external impact.

The performance of the display panel 110 may be evaluated by various indicators, such as reflectance, viewing angle, and element life. The reflectance refers to the degree of reflection of light incident on the display panel 110. The viewing angle represents the angle of light emitted from the emission layer EL. The element life refers to a period during which the display panel 110 operates normally, and the element life may be determined according to the material of the components inside the display panel 110. Hereinafter, an embodiment of the display device 100 is described that is capable of enhancing reflectance, viewing angle, and element life.

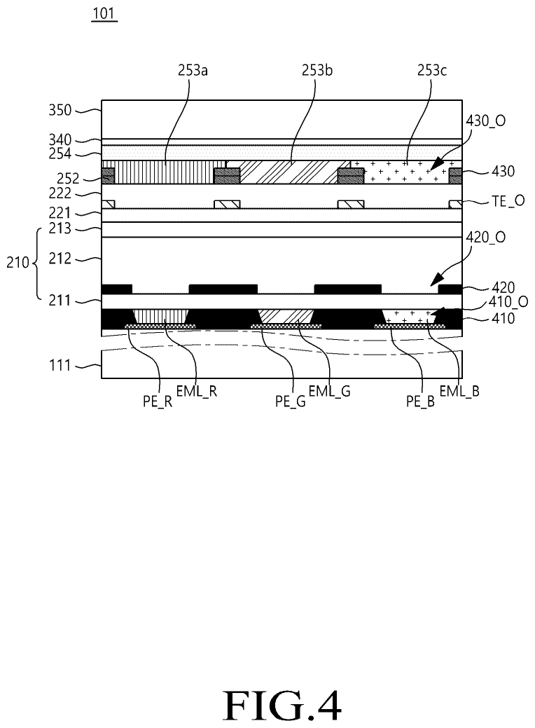

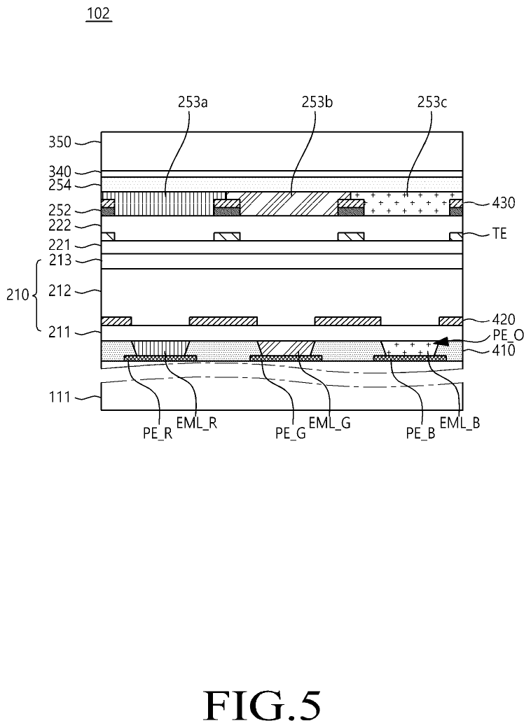

FIGS. 4 and 5 are cross-sectional views illustrating a display panel 101 according to embodiments of the disclosure.

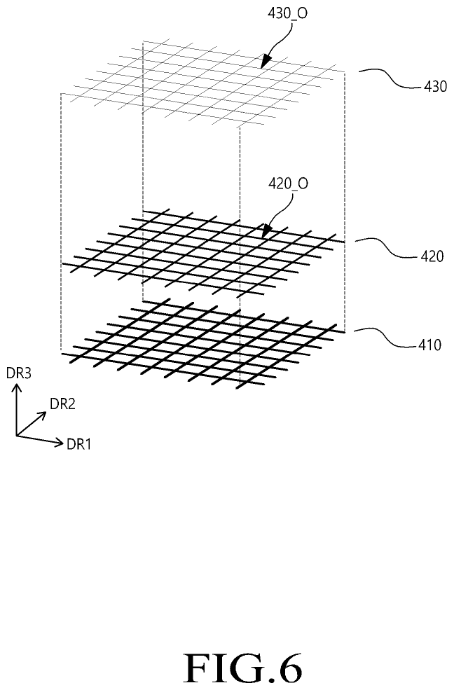

FIG. 6 is a detail view of a photochromic bank 410, a first photochromic layer 420, and a second photochromic layer 430 of the display panel 101 according to embodiments of the disclosure.

Referring to FIG. 4, the substrate 111 is disposed at a lowermost portion of the display panel 101.

Referring to FIG. 4, the anode electrodes PE_R, PE_G, and PE_B are disposed on the substrate 111. For convenience of description, layers disposed between the anode electrodes PE_R, PE_G, and PE_B and the substrate 111 are omitted from the drawings. In some embodiments, the layers disposed between the anode electrodes PE_R, PE_G, and PE_B and the substrate 111 are similar to or the same as the elements described above with reference to FIG. 3.

The anode electrodes PE_R, PE_G, and PE_B are pixel electrodes. The anode electrodes PE_R, PE_G, and PE_B are disposed to be spaced apart from each other.

After the anode electrodes PE_R, PE_G, and PE_B are disposed or formed on the substrate 111 during manufacturing, the photochromic bank 410 is disposed on the substrate 111.

A portion of the photochromic bank 410 overlaps the anode electrodes PE_R, PE_G, and PE_B.

The photochromic bank 410 defines an emission area. For example, the black bank 331, the bank 332, and the spacer 333 illustrated in FIG. 3 may be omitted from the display panel 101, and the photochromic bank 410 is included in the display panel 101 instead.

The photochromic bank 410 includes a polymer material that changes color according to the surrounding environment. For example, when exposed to an environment having ultraviolet (UV) light, the color of the photochromic bank 410 may turn black. When exposed to an environment without ultraviolet (UV) light, the photochromic bank 410 may turn transparent. Other configurations are possible depending on the composition and structure of the photochromic bank.

The photochromic bank 410 is disposed on the anode electrodes PE_R, PE_G, and PE_B and has an opening 410_O overlapping each of portions of the anode electrodes PE_R, PE_G, and PE_B.

Light emitting layers EML_R, EML_G, and EML_B are disposed in the emission area defined by the photochromic bank 410 and are specifically disposed in the openings 410_O in the photochromic bank 410, as shown in FIG. 4 and FIG. 5.

The light emitting layers EML_R, EML_G, and EML_B overlap the anode electrodes PE_R, PE_G, and PE_B. The first light emitting layer EML_R overlaps the first anode electrode PE_R. The second light emitting layer EML_G overlaps the second anode electrode PE_G. The third light emitting layer EML_B overlaps the third anode electrode PE_B.

A cathode electrode (not illustrated) is disposed on the light emitting layers EML_R, EML_G, and EML_B. The anode electrode, the light emitting layer, and the cathode electrode constitute a light emitting element.

The encapsulation layer 210 is disposed on the light emitting layers EML_R, EML_G, and EML_B. The encapsulation layer 210 includes a first inorganic encapsulation layer 211, an organic encapsulation layer 212, and a second inorganic encapsulation layer 213. The encapsulation layer 210 protects the light emitting layers EML_R, EML_G, and EML_B from external impacts and contaminants.

The first inorganic encapsulation layer 211 is disposed on the light emitting layers EML_R, EML_G, and EML_B and the photochromic bank 410. The first inorganic encapsulation layer 211 is an insulation layer including an inorganic material.

The first photochromic layer 420 is disposed on the first inorganic encapsulation layer 211.

The first photochromic layer 420 prevents interference between light emitted from the light emitting layers EML_R, EML_G, and EML_B.

The first photochromic layer 420 defines an emission area.

The first photochromic layer 420 overlaps the photochromic bank 410.

Like the photochromic bank 410, the first photochromic layer 420 includes a plurality of opening areas corresponding to the emission area or emission areas.

The first photochromic layer 420 includes a polymer material that changes color according to the surrounding environment. For example, when exposed to an environment having ultraviolet (UV) light, the color of the first photochromic layer 420 may turn black. When exposed to an environment without ultraviolet (UV) light, the color of the first photochromic layer 420 may turn transparent or may be transparent.

The organic encapsulation layer 212 is disposed on the first photochromic layer 420. The organic encapsulation layer 212 is an insulation layer including an organic material. The organic encapsulation layer 212 is thicker than the first inorganic encapsulation layer 211 and the second inorganic encapsulation layer 213.

The second inorganic encapsulation layer 213 is disposed on the organic encapsulation layer 212. The second inorganic encapsulation layer 213 is an insulation layer including an inorganic material.

The touch buffer layer 221 is disposed on the second inorganic encapsulation layer 213. The touch buffer layer 221 electrically insulates the touch metal TE from other components.

The touch metal TE has a mesh form. The touch metal TE is defined as a touch electrode. The touch electrode has openings TE_O overlapping the light emitting layers EML_R, EML_G, and EML_B, respectively. A portion of the touch electrode TE except for the opening TE_O overlap the first photochromic layer 420 and the second photochromic layer 430.

The black matrix 252 is disposed on the touch buffer layer 221. The black matrix 252 prevents color mixing of the light passing through the color filters 253a, 253b, and 253c. The black matrix 252 has a lattice shape.

The second photochromic layer 430 is disposed on the black matrix 252. The shape of the second photochromic layer 430 may be the same as the shape of the black matrix 252 and the second photochromic layer 430 may have a lattice shape.

The second photochromic layer 430 includes a polymer material that changes color according to the surrounding environment. For example, when exposed to an environment having ultraviolet (UV) light, the color of the second photochromic layer 430 may turn black. When exposed to an environment without ultraviolet (UV) light, the color of the second photochromic layer 430 may turn transparent.

The plurality of color filters 253a, 253b, and 253c are disposed on the touch buffer layer 221. Some of the plurality of color filters 253a, 253b, and 253c overlap the second photochromic layer 430 and the black matrix 252. The plurality of color filters 253a, 253b, and 253c overlap the light emitting layers EML_R, EML_G, and EML_B.

Each of the plurality of color filters 253a, 253b, and 253c is positioned on or in direct contact with at least a portion of the second photochromic layer 430.

The overcoat layer 254 is disposed on the plurality of color filters 253a, 253b, and 253c. The overcoat layer 254 protects the plurality of color filters 253a, 253b, and 253c from the outside.

The adhesive layer 340 and the cover window 350 are disposed on the overcoat layer 254.

Referring to FIGS. 4 and 5, the color of the photochromic bank 410, the first photochromic layer 420, and the second photochromic layer 430 may turn black or transparent according to a specific circumstance.

Referring to FIG. 4, the photochromic bank 410, the first photochromic layer 420, and the second photochromic layer 430 may be black as a result of these features being exposed to UV light, such as may occur when outdoors. In this case, the display panel 101 may be used outdoors with improved optical qualities. When the photochromic bank 410, the first photochromic layer 420, and the second photochromic layer 430 turn black, light reflectance is lowered, and thus visibility of the display panel 101 is enhanced or improved.

Referring to FIG. 5, the photochromic bank 410, the first photochromic layer 420, and the second photochromic layer 430 may be transparent as a result of these features being exposed to an environment without UV light, such as an indoor environment or a light-light environment. When the photochromic bank 410, the first photochromic layer 420, and the second photochromic layer 430 turn transparent, the viewing angle is increased.

As shown in FIG. 4 and FIG. 5, the photochromic bank 410, first photochromic layer 420, and second photochromic layer 430 are spaced from each other in the display layer stack. The photochromic bank 410 is a lowermost layer in the stack relative to the photochromic bank 410 and photochromic layers 420, 430. The first photochromic layer 420 is directly on the inorganic encapsulation layer 211 such that the first photochromic layer 420 is spaced from the photochromic bank 410 by at least the inorganic encapsulation layer 211 as well as any additional intervening layers between the photochromic bank 410 and the inorganic encapsulation layer 211. The second photochromic layer 430 is directly on the black matrix 252 with at least the organic encapsulation layer 212, the second inorganic encapsulation layer 213, the touch buffer layer 221, and the touch insulation layer 222 between the black matrix 252 and the first photochromic layer 420. Thus, the second photochromic layer 230 is spaced from the first photochromic layer 420 by a greater distance than the first photochromic layer 420 is spaced from the photochromic bank 410. In an embodiment, there are multiple layers of the display panel 101 layer stack between the second photochromic layer 430 and the first photochromic layer 420 while there may only be a single layer between the first photochromic layer 420 and the photochromic bank 410.

In addition, the display panel 101 may include more or less photochromic layers or structures than described above with respect to FIG. 4 and FIG. 5. For example, there may be more than one photochromic bank 410, more than one layer in the photochromic bank 410, or the photochromic bank 410 may be omitted. In another example, there is only a single photochromic layer 420 or 430 or more than two photochromic layers 420, 430 or at least one or both of the photochromic layers 420, 430 may be omitted. The display panel 101 can also have any of the photochromic layers or structures described herein in different locations of the layer stack than that shown and described with reference to FIG. 4 and FIG. 5. In some embodiments, the second photochromic layer 430 has the same shape and arrangement as the black matrix 252 meaning that the second photochromic layer 430 is formed only in locations that include the black matrix 252. Openings 430_O through the second photochromic layer 430 may have be the same, smaller, or larger in size than openings 420_O through the first photochromic layer 420. Preferably, the openings 430_O through the second photochromic layer 430 are larger than the openings 420_O through the first photochromic layer 420 so that the size, shape, and arrangement of the first photochromic layer 420 generally corresponds to the size, shape, and arrangement of the photochromic bank 410 (meaning the first photochromic layer 420 is formed only where the photochromic bank 410 is formed) while the size, shape, and arrangement of the second photochromic layer 430 corresponds to the black matrix, as above.

Referring to FIG. 6, each of the photochromic bank 410, the first photochromic layer 420, and the second photochromic layer 430 have a lattice structure.

The photochromic bank 410, the first photochromic layer 420, and the second photochromic layer 430 overlap each other.

The opening or openings 430_O of the second photochromic layer 430 are wider or larger than the opening or openings 420_O of the first photochromic layer 420. The opening 420_O of the first photochromic layer 420 be wider than the opening of the photochromic bank 410.

In other words, the width of the lattice shape of the second photochromic layer 430 is narrower than the width of the lattice shape of the first photochromic layer 420. The width of the lattice shape of the first photochromic layer 420 is narrower than the width of the lattice shape of the photochromic bank 410.

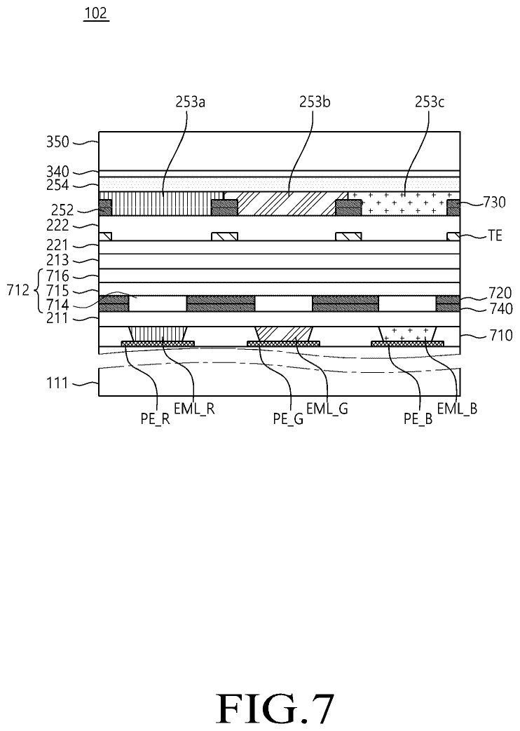

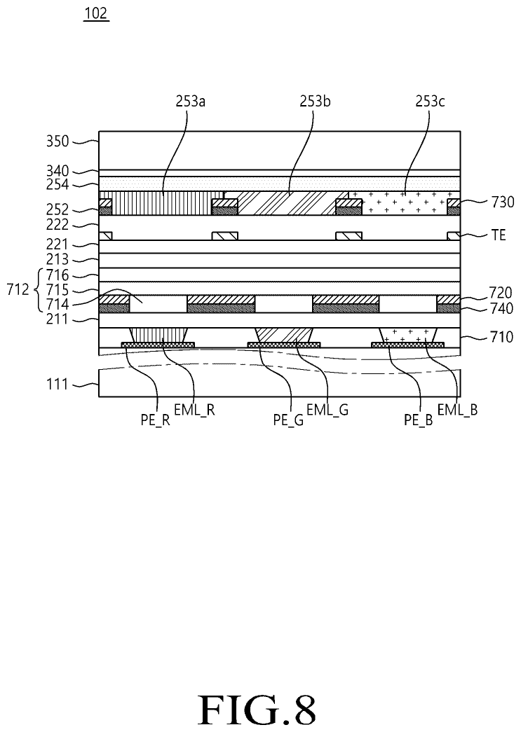

FIGS. 7 and 8 are cross-sectional views illustrating a display panel 102 according to embodiments of the disclosure.

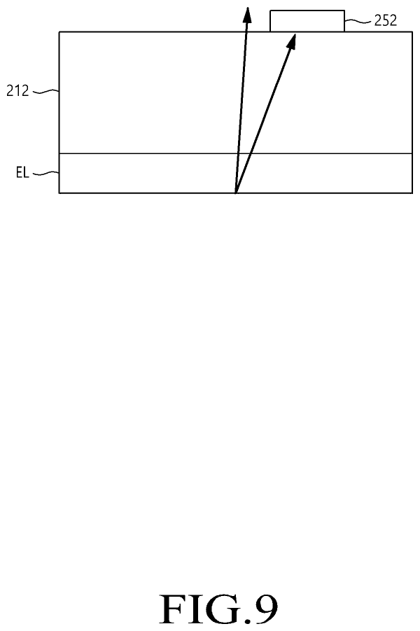

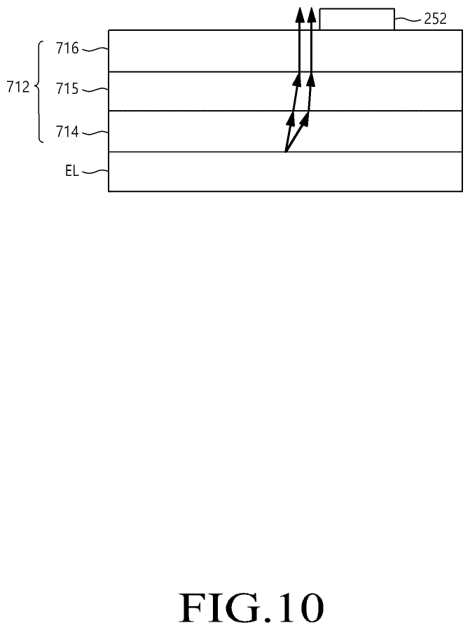

FIGS. 9 and 10 are cross-sectional views illustrating the encapsulation layer 210 of the display panel 110 of FIG. 4 and the organic encapsulation layer 712 of the display panel 102, respectively.

Referring to FIGS. 7 and 8, the display panel 102 includes an organic encapsulation layer 712 having a plurality of organic layers. For example, the organic encapsulation layer 712 includes at least two organic layers. Hereinafter, for convenience of description, it is assumed that the organic encapsulation layer 712 includes a first organic layer 714, a second organic layer 715, and a third organic layer 716.

A first photochromic layer 720 is disposed on the first inorganic encapsulation layer 211.

The black pixel defining layer 740 is disposed between the first photochromic layer 720 and the first inorganic encapsulation layer 211 and may also be referred to as a black bank 740 or black layer 740. The black pixel defining layer 740 prevents interference of the light emitted from the light emitting layer. The black pixel defining layer 740 includes a material that does not reflect light. For example, the black pixel defining layer 740 is black.

The first organic layer 714 is disposed to cover the first photochromic layer 720 and the first inorganic encapsulation layer 211. The refractive index of the first organic layer 714 may be referred to as a first refractive index.

The second organic layer 715 is disposed on the first organic layer 714. The refractive index of the second organic layer 715 may be referred to as a second refractive index. The second refractive index is preferably larger than the first refractive index.

The third organic layer 716 is disposed on the second organic layer 715. The refractive index of the third organic layer 716 may be referred to as a third refractive index. The third refractive index is preferably larger than the second refractive index such that the third refractive index is also greater than the second refractive index. In an embodiment, the first organic layer 714 fills the holes in the black layer 740 and the first photochromic layer 720 such that the first organic layer 714 is between the black layer 740 and the first photochromic layer 720. The second and third organic layers 715, 176 are stacked directly on top of each other and directly on the first photochromic layer 720 and the first organic layer 714. Thus, the second and third organic layers 715, 716 space the second photochromic layer 730 from the first photochromic layer 720.

Referring to FIG. 9, the propagation direction of light passing through the organic encapsulation layer 212 having a single layer of FIG. 4 is identified by arrows A. Light passing through the organic encapsulation layer 212 travels without refraction or otherwise changing its direction largely because the organic encapsulation layer 212 is a single layer with a constant refractive index, as further explained below.

Referring to FIG. 10, the propagation direction of the light passing through the organic encapsulation layer 712 of FIG. 7 or 8 is bent to the left, as shown by arrows B. When light travels from a relatively low refractive medium to a relatively high refractive medium, the propagation direction is refracted or changed. Due to the refractive index relationship between the first organic layer 714 and the third organic layer 716, the light passing through the organic encapsulation layer 712 is bent to the left. In other words, the propagation direction of light is bent toward the upper surface of the encapsulation layer 210. In other words, the light is directed to the center of the display panel 102 or the condensing power is enhanced. For example, light emitted from the emission area is emitted not only through the front but also through the side, and light emitted through the side is bent forward by the organic encapsulation layer 712 toward the front. The phase “bent forward” means traveling at an angle of 90 degrees or less toward the upper or front surface.

Some of the light illustrated in FIG. 9 is directed toward the black matrix 252 and is not emitted to the outside of the display panel 110. However, when the organic encapsulation layer 712 illustrated in FIG. 10 is applied, the corresponding light that is blocked or absorbed by the black matrix 252 in FIG. 9 is directed around the black matrix 252 to be emitted outside the display panel 110, thus improving luminance.

One or more embodiments of the disclosure described above are briefly described and summarized below.

Embodiments of the disclosure provide a display device comprising a substrate, a first pixel electrode disposed on the substrate, a second pixel electrode disposed on the substrate and spaced apart from the first pixel electrode, a bank disposed on the first pixel electrode and the second pixel electrode, overlapping each of a portion of the first pixel electrode and a portion of the second pixel electrode, and having an opening, a first light emitting layer disposed on the first pixel electrode, a second light emitting layer disposed on the second pixel electrode, a common electrode disposed on the first light emitting layer and the second light emitting layer, an inorganic encapsulation layer disposed on the common electrode, a first photochromic layer disposed on the inorganic encapsulation layer and overlapping the bank, an organic encapsulation layer disposed on the first photochromic layer, and a second photochromic layer disposed on the organic encapsulation layer and overlapping the first photochromic layer.

The display device further comprises a first color filter disposed on the organic encapsulation layer and overlapping the first light emitting layer, and a second color filter disposed on the organic encapsulation layer and overlapping the second light emitting layer.

A portion of the first color filter is positioned on a portion of the second photochromic layer, and a portion of the second color filter is positioned on a portion of the second photochromic layer.

The display device further comprises a touch electrode disposed on the organic encapsulation layer. The touch electrode has an opening overlapping each of the first light emitting layer and the second light emitting layer. A portion except for the opening in the touch electrode overlap the first photochromic layer and the second photochromic layer.

The display device further comprises an insulation layer on the touch electrode. The second photochromic layer be disposed on the insulation layer.

The organic encapsulation layer includes an organic material having a single refractive index.

The organic encapsulation layer includes a plurality of organic layers having different refractive indices.

The plurality of organic layers includes a first organic layer having a first refractive index, and a second organic layer disposed on the first organic layer and having a second refractive index larger than the first refractive index.

A propagation direction of light emitted from the light emitting layer is bent toward an upper surface of the encapsulation layer.

The first photochromic layer and the second photochromic layer are capable of turning transparent or black.

The first photochromic layer and the second photochromic layer turn black when exposed to ultraviolet (UV) light.

The first photochromic layer and the second photochromic layer turn transparent in a low-illuminance environment.

The bank include a photochromic material.

The bank turns black when exposed to UV light. Light toward the photochromic bank is relatively less reflected when the bank is black than when the bank is transparent.

The display device further comprises a black pixel defining layer disposed between the inorganic encapsulation layer and the first photochromic layer and overlapping the bank. The bank includes a transparent material. Light incident on the black pixel defining layer may be less reflected than when incident on the bank.

The bank, the first photochromic layer, and the second photochromic layer have a matrix form. The first photochromic layer and the second photochromic layer overlap the bank in an area of the bank other than the opening.

Embodiments of the disclosure provide a display device comprising a substrate, a bank disposed on the substrate and having an opening, a light emitting layer disposed in the opening, an inorganic encapsulation layer disposed on the light emitting layer and the bank, a first photochromic layer disposed on the inorganic encapsulation layer and overlapping the bank, and an organic encapsulation layer disposed on the first photochromic layer and including a plurality of organic layers having different refractive indices.

The plurality of organic layers include a first organic layer having a first refractive index, and a second organic layer disposed on the first organic layer and having a second refractive index larger than the first refractive index.

A propagation direction of light emitted from the light emitting layer be bent toward an upper surface of the encapsulation layer.

The first photochromic layer is capable of turning transparent or black.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the technical idea of the disclosure but do not limit the scope of the claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a first pixel electrode disposed on the substrate;
a second pixel electrode disposed on the substrate and spaced apart from the first pixel electrode;
a bank disposed on the first pixel electrode and the second pixel electrode, the bank overlapping a portion of the first pixel electrode and a portion of the second pixel electrode, the bank having an opening;
a first light emitting layer disposed on the first pixel electrode;
a second light emitting layer disposed on the second pixel electrode;
a common electrode disposed on the first light emitting layer and the second light emitting layer;
an inorganic encapsulation layer disposed on the common electrode;
a first photochromic layer disposed on the inorganic encapsulation layer and overlapping the bank;
an organic encapsulation layer disposed on the first photochromic layer; and
a second photochromic layer disposed on the organic encapsulation layer and overlapping the first photochromic layer.

2. The display device of claim 1, further comprising:
a first color filter disposed on the organic encapsulation layer and overlapping the first light emitting layer; and
a second color filter disposed on the organic encapsulation layer and overlapping the second light emitting layer,
wherein a portion of the first color filter is positioned on a portion of the second photochromic layer, and
wherein a portion of the second color filter is positioned on a portion of the second photochromic layer.

3. The display device of claim 1, further comprising a touch electrode disposed on the organic encapsulation layer,
wherein the touch electrode has an opening overlapping each of the first light emitting layer and the second light emitting layer, and
wherein a portion except for the opening in the touch electrode overlaps the first photochromic layer and the second photochromic layer.

4. The display device of claim 3, further comprising an insulation layer on the touch electrode,
wherein the second photochromic layer is disposed on the insulation layer.

5. The display device of claim 1, wherein the organic encapsulation layer includes an organic material having a single refractive index.

6. The display device of claim 1, wherein the organic encapsulation layer includes a plurality of organic layers having different refractive indices.

7. The display device of claim 6, wherein the plurality of organic layers include:
a first organic layer having a first refractive index; and
a second organic layer disposed on the first organic layer and having a second refractive index greater than the first refractive index.

8. The display device of claim 6, wherein the first light emitting layer and the second light emitting layer are configured to emit light and a propagation direction of light emitted from at least one of the first and second light emitting layers toward a side surface of the inorganic encapsulation layer is bent forward toward a front surface of the inorganic encapsulation layer.

9. The display device of claim 1, wherein the first photochromic layer and the second photochromic layer are capable of turning transparent or black.

10. The display device of claim 1, wherein the first photochromic layer and the second photochromic layer turn black when exposed to ultraviolet (UV) light.

11. The display device of claim 1, wherein the first photochromic layer and the second photochromic layer turn transparent in a low-illuminance environment.

12. The display device of claim 1, wherein the bank includes a photochromic material.

13. The display device of claim 12, wherein the bank turns black when exposed to UV light and turns transparent in a low-illuminance environment, and
wherein light emitted toward the photochromic bank by at least one of the first and second light emitting layers is relatively less reflected when the bank is black than when the bank is transparent.

14. The display device of claim 1, further comprising a black pixel defining layer disposed between the inorganic encapsulation layer and the first photochromic layer, the black pixel defining layer overlapping the bank,
wherein the bank includes a transparent material,
wherein light incident on the black pixel defining layer is less reflected than when incident on the bank, and
wherein the first photochromic layer overlaps the black pixel defining layer.

15. The display device of claim 1, wherein the bank, the first photochromic layer, and the second photochromic layer have a matrix form, and
wherein the first photochromic layer and the second photochromic layer overlap the bank in an area of the bank other than the opening.

16. A display device, comprising:
a substrate;
a bank disposed on the substrate and having an opening;
a light emitting layer disposed in the opening;
an inorganic encapsulation layer disposed on the light emitting layer and the bank;
a photochromic layer disposed on the inorganic encapsulation layer and overlapping the bank; and
an organic encapsulation layer disposed on the photochromic layer and including a plurality of organic layers having different refractive indices.

17. The display device of claim 16, wherein the plurality of organic layers include:
a first organic layer having a first refractive index; and
a second organic layer disposed on the first organic layer and having a second refractive index greater than the first refractive index.

18. The display device of claim 17, wherein a propagation direction of light emitted from the light emitting layer is bent toward an upper surface of the encapsulation layer.

19. The display device of claim 16, wherein the first photochromic layer is capable of turning transparent or black.

20. A display device, comprising:
a substrate;
a bank disposed on the substrate and having an opening;
a light emitting layer disposed in the opening;
an inorganic encapsulation layer disposed on the light emitting layer and the bank;
a first photochromic layer disposed on the inorganic encapsulation layer and overlapping the bank;
an organic encapsulation layer disposed on the first photochromic layer; and
a second photochromic layer disposed on the organic encapsulation layer and overlapping the first photochromic layer.
